(19) United States
(12) Patent Application Publication
(10) Pub. No.: US 2006/0138309 A1
(43) Pub. Date: Jun. 29, 2006

(54) Optical unit for lateral viewing duodenoscopes

(76) Inventor: Viktor Josef Wimmer, Seeon (DE)

Correspondence Address: ST. ONGE STEWARD JOHNSTON & REENS, LLC, 986 BEDFORD STREET, STAMFORD, CT, 06905-5619, US

(21) Appl. No.: 11/311,095

(22) Filed: Dec. 19, 2005

Related U.S. Application Data
(63) Continuation of application No. PCT/DE04/01274, filed on Jun. 18, 2004.

(30) Foreign Application Priority Data
Jun. 18, 2003 (DE) 103 27 747.1

(51) Int. Cl. H01J 3/14; H01L 27/00

(52) U.S. Cl. 250/216; 250/208.1

(57) ABSTRACT

The invention relates to an optical unit for duodenoscopes, wherein the light reflected along the length of direction Z by an illuminated object is guided in the direction Z through an optical system in an essentially perpendicular manner in relation to a CCD-chip. In relation to prior art, the optical unit is constructed in a simpler manner, is smaller, and is more resistant to leakages.

### CROSS-REFERENCE TO RELATED APPLICATIONS

The present application is a continuation of pending International patent application PCT/DE2004/001274 filed on Jun. 18, 2004 which designates the United States and claims priority of German patent application 103 27 747.1 filed on Jun. 18, 2003.

### FIELD OF THE INVENTION

The present invention relates to an optical unit for flexible video lateral-viewing duodenoscopes according to the general terms of Patent claim 1.

### BACKGROUND OF THE INVENTION

Video duodenoscopes have their field of application in medical technology, where examinations or medical interventions are to be undertaken inside the human body and in particular in the duodenal-papilla-gall canal.

Video duodenoscopes are distinguished, among other factors, by the fact that optical images from the body interior are transmitted outwards. In the process, light is conducted to the distal head end of the duodenoscope to illuminate areas that are to be investigated. In duodenoscopes in particular, an area to the side of the head is advantageously illuminated or processed (lateral-viewing duodenoscope). Light reflected from these areas enters the head from the side, is prepared by an optical system, and is guided while still inside the head to a so-called CCD-chip. This chip transforms the light signals into electric signals, which can be picked up and evaluated by an appropriate connection at the proximal end.

Familiar from practical applications are duodenoscopes in which the light rays reflected from the object travel through the optical system and then are routed to a deflection device, especially a prism, and then—possibly with additional optical preparation—reach the surface of the CCD-chip. The disadvantage of such devices consists, first, in the fact that the known deflection devices involve an increased construction expense. In addition they take up a certain amount of space in the head of the duodenoscope and thus stand in the way of attempts to minimize the size of the head. In addition such deflection devices involves losses, which have a negative effect on the reproduction and evaluation of the light signals.

An essential problem with such duodenoscopes, in addition, is hygiene. The cleansing of the duodenoscope's components, as required for operational interventions, runs the risk that it can itself damage the components, and in particular moisture can penetrate into the head or, for instance, the optical components. Therefore the optical units are difficult to make water-resistant.

### SUMMARY OF THE INVENTION

It is therefore the object of the invention to offer an optical unit which, in a small structural size, allows an improved image production, and is easier to clean and less prone to soiling.

This object is fulfilled through an optical unit according to Patent claim 1.

The invention is based on the recognition that a shortening of the head length (in the longitudinal direction of the duodenoscope) is possible and especially advantageous when the CCD-chip is positioned immediately under the optical system, so that the light signals that are falling into the optical unit essentially along an axial length of direction Z and are prepared, reach the surface of the CCD-chip immediately and preferably perpendicular to the length of direction Z The chip here is thus not, as customary in prior art, positioned through a prism or the like or angled around a mass from the axial direction of the optical system. A deflection device is now superfluous. The optical system and the CCD-chip thus form the essential components of the optical unit.

The light signals, which from the illuminated object enter the head and thus the optical system laterally, are thus prepared in this system, for instance by being conducted through it by a lens packet. The optical system is essentially positioned along an axial length of direction Z, so that the prepared light signals also leave the optical system again along the axial length of direction Z. Without using a deflection device, and with the CCD-chip arranged immediately in this direction Z, deflection losses are avoided, so that a better image quality can advantageously be achieved. In particular, the illuminated object, the optical system, and the CCD-chip therefore lie essentially in a straight line.

As an additional advantage, moreover, the head of the duodenoscope on the one hand is of smaller overall structure because of the absence of deflection device, and moreover because of the rearrangement of the CCD-chip in the axial direction Z, it becomes possible to minimize in particular the longitudinal extension of the duodenoscope head. In an observation in the longitudinal direction of the duodenoscope from the proximal end to the distal end, the CCD-chip now no longer lies between the proximal end and the optical system, but almost on the same height with the optical system, so that the head can be structured shorter by the length that has thus been saved.

In an advantageous embodiment of the invention, the optical system is equipped with appropriate lenses, so that the captured light signals, bundled or scattered, strike the CCD-chip or its light-sensitive surface. Through appropriate selection of the lens system, the image quality can be substantially improved, without deflection losses or diffraction effects worsening this result by means of the deflection device.

In an additional advantageous embodiment, the optical unit constitutes a one-part unit, which in particular includes the optical system and the CCD-chip. Here “one-part” is to be understood as meaning that the optical system and the CCD-chip are positioned fixed to one another in an optical unit that is at first movable in itself. One particular possibility is an essentially cylindrical construction. The advantage resides in the modular-type applicability. CCD-chip and optical system can—for instance, under conditions of particular cleanliness—be at first directed and fixed to one another, before they are inserted together into the head of the duodenoscope.

It can be particularly advantageous if the optical unit here is made up particularly of the optical system and CCD-chip, through cementing, bolting, notching, or soldering of the components. Here, rather than immediately using these components, carrier elements can also be connected to one another which, in turn, hold the components. The aforementioned means of fixing them together can lead, on the one hand, to a special ease of installation; on the other hand, the optical unit can be insulated against moisture in its own right, especially before installation while still outside the head, a result that is possible by means of appropriate cement, insulating elements, and the like. Thus it is possible to avoid penetration of dampness into the optical unit, such as between the optical system and the CCD-chip, if the unit is assembled according to prior art, for instance only in the head.

An additional advantageous embodiment of the invention foresees configuring the optical unit so that it can be inserted into, or removed from, a largely complementary opening of the head (2). By inserting the unit as a whole into the head, its installation is simplified, especially because the customary deflection device according to prior art is now dispensed with. The entire unit can be inserted into the head in an axial pushing motion, preferably heading in the Z direction. There it can be soldered or cemented to the head. Subsequent removal or replacement is also possible and even easy because there is no need here for the angle construction of the optical unit that was necessary in prior art.

Various angles of construction between the main longitudinal axis of the duodenoscope and the direction Z can be used to particular advantage. According to prior art, while maintaining the CCD-chip arrangement in the head, only another deflection angle of the prism could correct a modified arrangement of the optical system. The optical unit as a whole therefore needs to be changed. If it is desired to keep the CCD-chip, deflection device, and optical system unchanged with respect to one another, then the head must be essentially reconfigured, which is even less desirable.

Much more simply, the optical unit according to the present invention also allows various angles of entry. This requires only that the opening in the head of the duodenoscope, which is cylindrical for instance and in which the optical unit is inserted, is positioned differently. In the new position, and thus at a new angle to the main longitudinal axis, the entire optical unit can be inserted. Thus it is possible, for instance, to record an image of a different area outside the head.

According to another advantageous embodiment of the invention, the optical unit can be inserted into the opening of the head (2) by cementing, soldering, notching, or bolding. Here, depending on the material of the optical unit or of its components, an appropriate process can be used advantageously, particularly to ensure insulation of the head against substances penetrating inside the head. The area between the optical unit and the opening into which it is inserted, for instance, can be closed with insulating material.

The optical unit or its components can consist in particular of metal, glass, plastic, or other materials appropriate to medical technology.

Additional advantageous embodiments can be seen in the subsidiary Patent Claims.

### BRIEF DESCRIPTION OF THE DRAWINGS

An embodiment of the invention is further described hereafter with reference to an illustrated example. FIG. 1, the only illustration, shows a schematic sectional depiction through an inventive duodenoscope.

FIG. 1 shows in particular the head 2 of a duodenoscope 1. The exemplary duodenoscope head has on its distal end a water canal 9. In addition, a light conductor 6 is provided, which allows the exiting of illuminating light laterally at the duodenoscope head 2. An exhaust canal 4 is also indicated.

### DETAILED DESCRIPTION OF THE INVENTION

The object illuminated by the light conductor 6 reflects light signals L. The light signals L enter the optical system 3, which is configured essentially axially along a length of direction Z. The optical system includes lenses and other optical elements, which are appropriate for bundling or filtering the light signals.

A CCD-chip 5 is arranged in direction Z. The CCD-chip 5 has a surface 7 on which the prepared light signals L land. The surface 7 is positioned essentially vertical to the axial direction Z, so that the light signals, coming from the object upward into the optical system 3 or exiting from it, land essentially vertically on the CCD-chip.

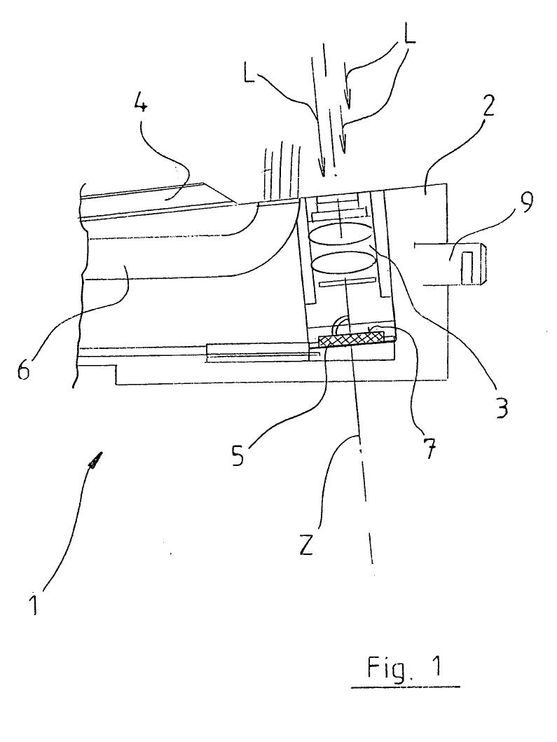

The signals transformed in the CCD-chip are than conducted to the proximal end of the duodenoscope head (heading away toward the left in FIG. 1).

What is claimed is:

1. An optical unit for the distal head of lateral-viewing duodenoscopes, having
a) an optical system for optical preparation of light signals, wherein the light signals
a1) enter the optical system from outside the head in an axial direction and
a2) run through the optical system essentially in this direction, and having
b) a CCD-chip alongside the optical system for transforming the light signals that land on a surface of the CCD-chip, distinguished in that
c) the length of direction passes through the surface essentially perpendicularly.

2. An optical unit according to claim 1, characterized in that the optical system is a lens system.

3. An optical unit according to claim 1, distinguished in that the optical system and the CCD-chip are combined in a one-part unit.

4. An optical unit according to claim 3, distinguished in that the unit is configured by cementing, bolting, notching, or soldering the components of the optical unit.

5. An optical unit according to claim 1, distinguished in that the optical unit can be inserted into and/or removed from an opening of the head.

6. An optical unit according to claim 5, distinguished in that the optical unit can be inserted into the opening of the head by cementing, soldering, notching, or bolting.

7. An optical unit according to claim 1, distinguished in that the light signals in the optical unit are not deviated by a deflection device, in particularly a prism.

8. An optical unit according to claim 1, distinguished in that the area between the optical unit and the opening that receives it is closed with insulating material.
